(19) United States
(12) Patent Application Publication
(10) Pub. No.: US 2015/0175811 A1
(43) Pub. Date: Jun. 25, 2015

(54) SILVER-SULFIDATION-PREVENTING MATERIAL AND METHOD FOR FORMING SILVER-SULFIDATION-PREVENTING FILM, AND METHOD FOR PRODUCING LIGHT-EMITTING DEVICE AND LIGHT-EMITTING DEVICE

(71) Applicant: HITACHI CHEMICAL COMPANY, LTD., Tokyo (JP)

(72) Inventors: Maki Inada, Tsukuba-shi (JP); Masashi Yamaura, Tsukuba-shi (JP); Nobuaki Takane, Tsukuba-shi (JP); Tomoko Higashiuchi, Tsukuba-shi (JP)

(73) Assignee: Hitachi Chemical Company, Ltd., Tokyo (JP)

(21) Appl. No.: 14/415,815

(22) PCT Filed: Jul. 17, 2013
(86) PCT No.: PCT/JP2013/069402

§ 371 Date: Jan. 20, 2015

(30) Foreign Application Priority Data
Jul. 20, 2012 (JP) 2012-161799

(51) Int. Cl. C09D 5/08; H01L 33/44; H01L 33/60

(52) U.S. Cl. CPC C09D 5/084; H01L 33/60; H01L 33/44; H01L 2933/0025; H01L 2933/0058

(57) ABSTRACT

A silver-sulfidation-preventing material of the present invention comprises clay and a binder.

### TECHNICAL FIELD

The present invention relates to a silver-sulfidation-preventing material, and particularly relates to a silver-sulfidation-preventing material for preventing discoloration caused by sulfidation of silver plating used for a light-emitting device or the like. The present invention relates to a method for forming a silver-sulfidation-preventing film using the silver-sulfidation-preventing material, and a method for producing a light-emitting device.

### BACKGROUND ART

In recent years, demand for a light emitting diode (LED) has rapidly increased as a light source used in place of a fluorescent light or a filament lamp. A light-emitting device comprising a light-emitting element such as the light emitting diode is used for applications such as a lighting device and an automobile light. In such a light-emitting device, an improvement in light extraction efficiency is achieved by providing a light reflection film made of silver plating. For example, in an LED package comprising a lead frame such as a copper plating substrate, reflectance is improved by providing a silver plating layer on a copper plating layer (see the following Patent Literature 1).

### CITATION LIST

### Patent Literature

Patent Literature 1: Japanese Patent Application Laid-Open No. 2009-239116

### SUMMARY OF INVENTION

### Technical Problem

In an LED package, a light-emitting element and a light reflection film or the like are usually protected by sealing by a transparent resin. However, when a light-emitting device is used outside, a problem occurs that hydrogen sulfide and sulfurous acid gas or the like in the environment penetrate the resin to sulfidize the silver plating, and the optical reflectance of the silver plating is decreased by discoloration. Recently, the amount of heat generation of an LED increases with an increase in power of the LED, and the sulfidation of the silver plating tends to be further accelerated with an increase in temperature.

In light of the circumstances, an object of the present invention is to provide a silver-sulfidation-preventing material capable of sufficiently suppressing sulfidation of silver, a method for forming a silver-sulfidation-preventing film using the same, a light-emitting device having excellent silver-sulfidation-preventing property, and a method for producing the same.

### Solution to Problem

In order to solve the problems, the present invention provides a silver-sulfidation-preventing material comprising: clay and a binder.

A silver-sulfidation-preventing film capable of sufficiently suppressing sulfidation of silver can be formed by applying the silver-sulfidation-preventing material of the present invention onto a surface of a metal layer containing silver, and drying the silver-sulfidation-preventing material.

In the meantime, when the silver-sulfidation-preventing material is applied to a silver plating layer of an LED package, a step of forming the silver-sulfidation-preventing film on the silver plating layer is considered to be provided before or after parts such as a light-emitting element and a reflector are mounted on a substrate. Since the silver-sulfidation-preventing film is heated in processes for sealing or the like in both the cases, heat resistance is required for the silver-sulfidation-preventing film. When the silver-sulfidation-preventing film is formed and when an LED is turned on, heat has an influence on the silver-sulfidation-preventing film. It is considered to use a resin having high heat resistance such as a silicone resin as a method for forming a film having excellent heat resistance. However, the silicone resin has low gas barrier properties, which does not provide sufficient silver-sulfidation-preventing property. A high temperature process at 300° C. or more to melt glass to form a coat is required for a method for forming an inorganic coat such as glass, and the method cannot be applied to the LED package.

In contrast, the silver-sulfidation-preventing material of the present invention can form a silver-sulfidation-preventing film having sufficient heat resistance and silver-sulfidation-preventing property at a process temperature capable of being applied to the LED package, and excellent crack resistance.

On the other hand, higher-level silver-sulfidation-preventing property may be required. In this case, it is considered to increase the film thickness of the sulfidation preventive film. However, the film including the clay is apt to generate cracks when the film thickness is set to 500 nm or more. The silver-sulfidation-preventing material of the present invention can form a clay film which is less likely to generate cracks even when the film thickness is increased. Thereby, higher silver-sulfidation-preventing property can be obtained by increasing the film thickness of the silver-sulfidation-preventing film.

From the viewpoint of further increasing the crack resistance of the silver-sulfidation-preventing film to be formed, a mass ratio of the clay to the binder is preferably 75/25 to 5/95.

The silver-sulfidation-preventing material of the present invention preferably comprises an aqueous binder as the binder. In this case, the clay and the binder can be satisfactorily mixed in water and/or a water-soluble liquid, and a silver-sulfidation-preventing film in which film formability is further improved can be formed.

The aqueous binder herein refers to a binder having a macroscopically uniform state such as a solution, an aqueous solution, an emulsified matter, and a solubilized matter when the aqueous binder is mixed with water and/or a water-soluble liquid.

From the viewpoint of further increasing the silver-sulfidation-preventing property, a total content of the clay and the binder is preferably 80% by mass or more based on a total amount of a solid content of the silver-sulfidation-preventing material.

The total mass of the solid content of the silver-sulfidation-preventing material refers to a value obtained by the following method. The silver-sulfidation-preventing material is put on an aluminum pan, and the mass of the silver-sulfidation-preventing material after being dried at 150° C. for 2 hours is measured.

When the concentration of the solid content of the silver-sulfidation-preventing material is determined, the silver-sulfidation-preventing material is put on the aluminum pan; the mass of the silver-sulfidation-preventing material is measured; and then, the concentration of the solid content can be calculated according to the following formula from a value obtained by measuring the mass of the silver-sulfidation-preventing material after being dried at 150° C. for 2 hours.

Concentration of Solid Content=(Mass After being Dried)/(Mass Before being Dried)×100

The present invention provides a method for forming a silver-sulfidation-preventing film, the method comprising: an applying step of applying the silver-sulfidation-preventing material according to the present invention onto a surface of a metal layer comprising silver to form a coated film made of the silver-sulfidation-preventing material; and a drying step of drying the coated film.

The method for forming a silver-sulfidation-preventing film of the present invention can form a silver-sulfidation-preventing film capable of sufficiently suppressing sulfidation of silver using the silver-sulfidation-preventing material according to the present invention.

The silver-sulfidation-preventing film having excellent heat resistance such as yellowing resistance can be formed by using the silver-sulfidation-preventing material according to the present invention. Furthermore, even when a silver-sulfidation-preventing film having high silver-sulfidation-preventing property is formed by increasing a film thickness, the generation of cracks can be suppressed by using the silver-sulfidation-preventing material according to the present invention.

The metal layer is preferably a silver plating layer. In this case, a decrease in the optical reflectance of the silver plating layer due to sulfidation can be prevented.

The present invention provides a method for producing a light-emitting device, the light-emitting device comprising a substrate having a silver plating layer, and a light-emitting element mounted on the substrate, the method comprising: an applying step of applying the silver-sulfidation-preventing material according to the present invention onto a surface of the silver plating layer to form a coated film made of the silver-sulfidation-preventing material; and a drying step of drying the coated film.

The method for producing a light-emitting device of the present invention can form a silver-sulfidation-preventing film capable of sufficiently suppressing sulfidation of silver on the surface of the silver plating layer, and thereby, the method can produce a light-emitting device in which discoloration of the silver plating layer is less likely to occur and which has excellent silver-sulfidation-preventing property.

Since the method for producing a light-emitting device of the present invention can form a silver-sulfidation-preventing film having excellent heat resistance such as yellowing resistance using the silver-sulfidation-preventing material according to the present invention, the method can sufficiently suppress producing problems caused by coloring at a process temperature for sealing or the like. Since a silver-sulfidation-preventing film which is less likely to turn yellow by heating during lighting can be formed in the obtained light-emitting device, a decrease in reflectance caused by coloring can be sufficiently suppressed.

Furthermore, since the method for producing a light-emitting device of the present invention can form a silver-sulfidation-preventing film which is less likely to generate cracks even when the silver-sulfidation-preventing film is a thick film, by using the silver-sulfidation-preventing material according to the present invention, the method can produce a light-emitting device having high-level silver-sulfidation-preventing property while sufficiently suppressing problems in manufacturing caused by the cracks of the film.

The present invention provides a light-emitting device comprising: a substrate having a silver plating layer; a light-emitting element mounted on the substrate; and a silver-sulfidation-preventing film provided on a surface of the silver plating layer, wherein the silver-sulfidation-preventing film comprises clay and a binder.

Since the light-emitting device of the present invention comprises the silver-sulfidation-preventing film, the light-emitting device has excellent silver-sulfidation-preventing property, and the silver plating layer is less likely to be discolored. Since the silver-sulfidation-preventing film has excellent heat resistance such as yellowing resistance, a decrease in reflectance caused by the coloring of the silver-sulfidation-preventing film by heating during lighting can be sufficiently suppressed.

In point of excellent crack resistance, a mass ratio of the clay and the binder in the silver-sulfidation-preventing film is preferably 75/25 to 5/95.

The silver-sulfidation-preventing film preferably comprises an aqueous binder as the binder. In this case, when the silver-sulfidation-preventing film is formed, the clay and the binder can be satisfactorily mixed in water and/or a water-soluble liquid, and thereby the film formability of the silver-sulfidation-preventing film is further improved.

From the viewpoint of further increasing the silver-sulfidation-preventing property, a total concentration of the clay and the binder in the silver-sulfidation-preventing film is preferably 80% by mass or more.

### Advantageous Effects of Invention

The present invention can provide a silver-sulfidation-preventing material capable of sufficiently suppressing sulfidation of silver, a method for forming a silver-sulfidation-preventing film using the same, a light-emitting device having excellent silver-sulfidation-preventing property, and a method for producing the same.

### BRIEF DESCRIPTION OF DRAWINGS

FIG. 1 is a sectional view of a light-emitting device.

FIG. 2 is a plan view of the light-emitting device shown in FIG. 1.

FIG. 3 is a flow chart showing a method for producing a light-emitting device according to a first embodiment.

FIG. 4 is a sectional view of a light-emitting device after an applying step of a silver-sulfidation-preventing material according to an embodiment.

FIG. 5 is a sectional view of a light-emitting device after a drying step.

FIG. 6 is a sectional view of a light-emitting device after a transparent sealing resin filling step.

FIG. 7 is a conceptual view for describing a constitution of a silver-sulfidation-preventing film formed from a silver-sulfidation-preventing material according to an embodiment.

FIG. 8 is a flow chart showing a method for producing a light-emitting device according to a second embodiment.

FIG. 9 is a sectional view of the light-emitting device produced by the producing method of FIG. 8.

FIG. 10 is a flow chart showing a method for producing a light-emitting device according to a third embodiment.

FIG. 11 is a sectional view of the light-emitting device produced by the producing method of FIG. 10.

### DESCRIPTION OF EMBODIMENTS

A silver-sulfidation-preventing material according to the present embodiment contains clay and a binder. The silver-sulfidation-preventing material can contain a solvent for dispersing the clay and the binder. A silver-sulfidation-preventing film capable of sufficiently suppressing sulfidation of silver can be formed by applying the silver-sulfidation-preventing material of the present embodiment onto a surface of a metal layer containing silver, and drying the silver-sulfidation-preventing material. Examples of the metal layer include a silver plating layer and a silver paste layer.

Natural clay, synthetic clay, and modified products thereof may be used either singly or in combination of two or more as the clay.

For example, the following layered silicates can be used as the natural clay. Specific examples include kaolin, talc-pyrophyllite, smectite, vermiculite, isinglass (mica), brittle mica, and chlorite. Typical examples of kinds include lizardite, amesite, chrysotile, kaolinite, dickite, halloysite, talc, pyrophyllite, saponite, hectorite, montmorillonite, beidellite, three octahedron type vermiculite, two octahedron type vermiculite, bronze mica, black mica, lepidolite, illite, white mica, paragonite, clintonite, margarite, clinochlore, chamosite, nimite, donbassite, cookeite, and sudoite. Examples of commercially available products include Kunipia (trade name: Kunipia F manufactured by Kunimine Industries Co., Ltd.) and wet-milled mica (Y series, SA series manufactured by Yamaguchi Mica Co., Ltd.).

Examples of the synthetic clay include fluorine bronze mica, potassium tetrasilicon mica, sodium tetrasilicon mica, Na taeniolite, Li taeniolite, montmorillonite, saponite, hectorite, and stevensite. Examples of commercially available products include micro mica, SOMASIF (trade name: MEB-3 manufactured by Co-op Chemical Co., Ltd.), Lucentite (trade name: SWN manufactured by Co-op Chemical Co., Ltd.), and swellable mica sol (NTS-10, NTS-5 manufactured by Topy Industries Ltd.).

Examples of commercially available products of the modified products of the synthetic clay include SOMASIF (trade name: MAE manufactured by Co-op Chemical Co., Ltd.), and Lucentite (trade name: SPN manufactured by Co-op Chemical Co., Ltd.).

In the present embodiment, from the viewpoint of improving the silver-sulfidation-preventing property of the silver-sulfidation-preventing film to be formed, it is preferable to contain montmorillonite as the clay. The montmorillonite preferably has a shape having a thickness of 1 nm or less and a length in a diametrical direction of 10 nm or more and 400 nm or less, and more preferably has an aspect ratio of 10 or more. The aspect ratio herein means average long side length/average thickness of crystals.

Examples of the binder include an urethane resin, a polyamide resin, a polyester resin, a polyether resin, polycarbonate, a diene-based polymer, polyvinyl alcohol, polyvinyl acetal, xanthan gum, and carboxymethyl cellulose.

When water or a water-soluble liquid is used as the solvent, from the viewpoint of providing good mixture with the clay, the binder is preferably an aqueous binder. Examples of the aqueous binder include emulsions of polyurethane and polyester or the like, a vinyl alcohol-based resin emulsion, a vinyl acetal-based resin emulsion, an acrylic resin emulsion, a sulfonated emulsion of a diene-based polymer, carboxymethyl cellulose, xanthan gum, an epoxy-based emulsion, and a polyamide-based emulsion.

Furthermore, from the viewpoints of barrier properties, heat resistance, and crack resistance, the emulsions of polyurethane and polyester or the like, the sulfonated emulsion of the diene-based polymer, the epoxy-based emulsion, the polyamide-based emulsion, and the vinyl acetal-based resin are preferable, and the polyurethane emulsion and the vinyl acetal-based resin are more preferable. The polyurethane emulsion is preferably a self-emulsifying polyether-based polyurethane emulsion, a self-emulsifying polyester-based polyurethane emulsion, and a self-emulsifying polycarbonate-based polyurethane emulsion.

From the viewpoint of the compatibility with the solvent and the clay, the vinyl acetal-based resin is preferably a vinyl acetal resin having the following structural unit obtainable by partially acetalizing polyvinyl alcohol:

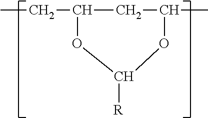

wherein R represents an alkyl group having 1-10 carbon atoms; and a butyral resin in which R is a propyl group is more preferable.

The degree of acetalization of the vinyl acetal resin is preferably 5 mol % to 80 mol % in the vinyl acetal resin. Yellowing caused by heating when the silver-sulfidation-preventing film is formed can be suppressed by using such a binder, and the heat resistance of the formed silver-sulfidation-preventing film can be further improved.

In the silver-sulfidation-preventing material of the present embodiment, from the viewpoint of increasing the crack resistance of the silver-sulfidation-preventing film to be formed, a mass ratio of the clay to the binder is preferably 75/25 to 5/95. From the viewpoint of achieving both the crack resistance and the silver-sulfidation-preventing property, the mass ratio of the clay to the binder is preferably 70/30 to 10/90, and from the viewpoint of further achieving the heat resistance, the mass ratio is more preferably 50/50 to 15/85.

In the silver-sulfidation-preventing material of the present embodiment, from the viewpoint of improving the silver sulfidation preventive performance of the silver-sulfidation-preventing film, a total content of the clay and the binder is preferably 80% by mass or more, more preferably 85% by mass or more, and further preferably 90% by mass or more based on a total amount of a solid content of the silver-sulfidation-preventing material.

From the viewpoint of improving the silver sulfidation preventive performance of the silver-sulfidation-preventing film, the concentration of the clay in the silver-sulfidation-preventing material of the present embodiment is preferably 0.05% by mass or more and 50% by mass or less based on the total amount of the silver-sulfidation-preventing material, more preferably 0.1% by mass or more and 20% by mass or less, and further preferably 0.2% by mass or more and 10% by mass or less.

The silver-sulfidation-preventing material of the present embodiment may be a form in which different liquid compositions containing the clay and the binder respectively are mixed when used. That is, the silver-sulfidation-preventing material of the present embodiment may be a one-pack type or a two or more-pack type.

Examples of the solvent include water and a water-soluble liquid.

For example, ultrapure water is used as the water. The ultrapure water is water containing a trace amount of ionic impurities, and water in which a theoretical value at 25° C. with an electric resistivity (specific resistance, MΩ·cm) (JIS K0552) as an index is 15 MΩ·cm or more, and preferably 18 MΩ·cm or more can be used.

Examples of the water-soluble liquid include polar solvents such as alcohol, and specifically, liquids such as ethanol, methanol, isopropyl alcohol, n-propyl alcohol, dioxane, acetone, acetonitrile, diethylamine, n-butyl alcohol, tert-butyl alcohol, pyridine, N,N-dimethylformamide, dimethyl sulfoxide, sulfolane, N-methylpyrrolidone, propylene carbonate, γ-butyrolactone, formamide, allyl alcohol, acrylic acid, acetic acid, ethylene glycol, propylene glycol, glycerin, methacrylic acid, butanoic acid, trimethylamine, triethylamine, ammonia, and diethyl sulfite can be employed. The water-soluble liquid refers to a water-soluble liquid in which a mixed solution of the water-soluble liquid and pure water of the same volume maintains a uniform appearance even after the flowage is settled when the water-soluble liquid and the pure water are gently stirred at a temperature of 20° C. at 1 atmosphere. The water-soluble liquids may be used either singly or in combination of two or more.

From the viewpoint of improving the silver-sulfidation-preventing property of the silver-sulfidation-preventing film to be formed when the mixture of the water and the water-soluble liquid is used as the solvent in the present embodiment, a mass ratio of the water to the water-soluble liquid is preferably 99/1 to 5/95, more preferably 95/5 to 20/80, and further preferably 90/10 to 50/50.

Various additive agents can be added to the silver-sulfidation-preventing material of the present embodiment within a range not impairing the effects of the present invention. Examples of the additive agents include an ion scavenger, a surface-active agent, a rust inhibitor, and a coupling agent.

Examples of a method for preparing the silver-sulfidation-preventing material of the present embodiment include a method involving adding clay, a binder, and the additive agent if needed to a solvent containing water, dispersing these materials, and stirring the dispersed solution. A general method for dispersing a powder in a liquid can be used for the stirring. For example, the stirring can be performed by using a rotation/revolution mixer, a supersonic method, a media dispersion method such as a bead mill and a ball mill, a homomixer, a counter collision method such as a silverson stirrer and Altimizer, a propeller type stirrer, a stirring bar, and a shaker or the like. These dispersion methods may be used either singly or in combination of two or more.

The silver-sulfidation-preventing material of the present embodiment is applied onto the surface of the metal layer containing silver, and dried, and thereby the silver-sulfidation-preventing film capable of sufficiently suppressing sulfidation of silver can be formed on the surface of the metal layer.

The silver-sulfidation-preventing material of the present embodiment can form a clay film which is less likely to generate cracks even if the thickness is 0.3 nm or more. Particularly, the thickness of the silver-sulfidation-preventing film is set to 0.01 to 1000 nm, and preferably 0.05 to 100 nm, and thereby both crack resistance and excellent silver-sulfidation-preventing property can be achieved.

The present inventors consider the reason why the silver-sulfidation-preventing film having excellent adhesion, crack resistance, and silver-sulfidation-preventing property can be formed by the silver-sulfidation-preventing material of the present embodiment as follows. That is, the binder adsorbing on the surface of a clay compound is subjected to a drying treatment, and can bind adjacent molecules, and thereby the reason why the effect is obtained is considered to be because adhesion properties between layers of the clay compound and between the surface of the clay compound and silver can be increased. In the case of a reflector, it is considered that the adhesion properties between the surface of the clay compound, and a reflector resin, a transparent sealing resin, and a silver reflective film which constitute the reflector can be further increased.

Next, preferred embodiments of a method for forming a silver-sulfidation-preventing film using a silver-sulfidation-preventing material of the present embodiment, and a method for producing a light-emitting element will be described with reference to the drawings. Identical or corresponding parts in all the drawings will be referred to by like reference signs.

### First Embodiment

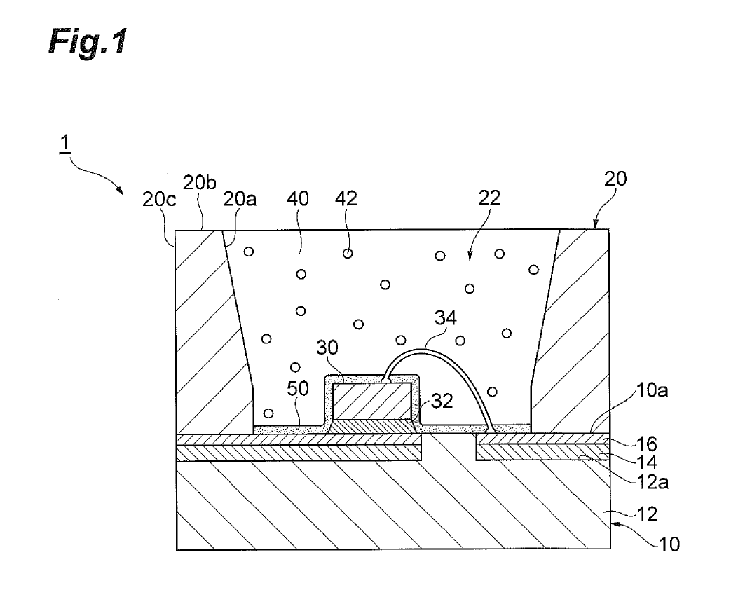

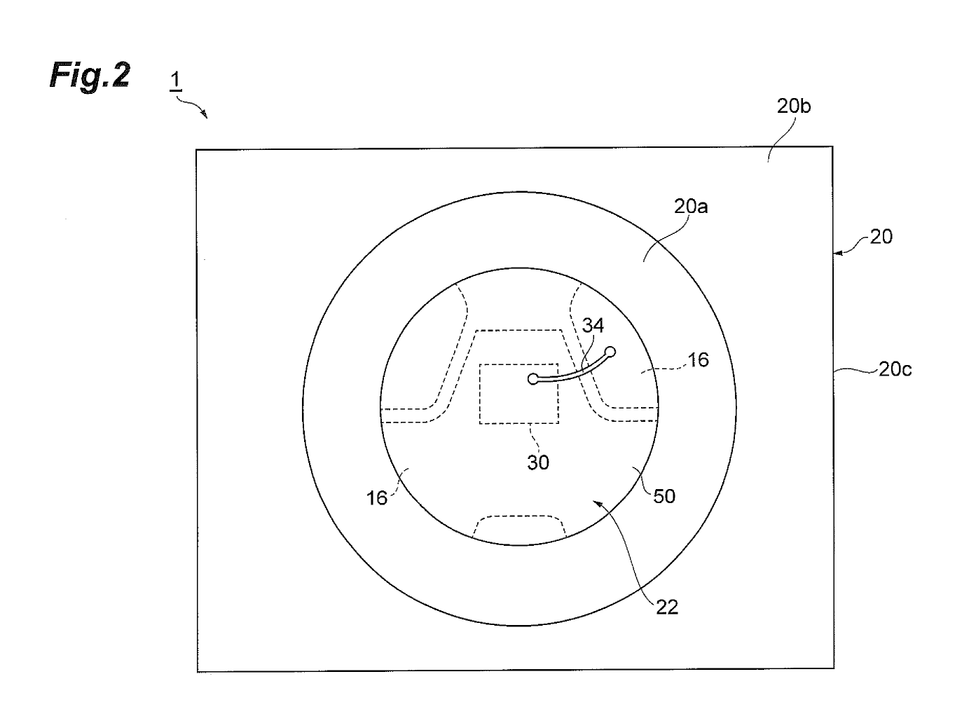

First, before the method for producing a light-emitting device according to the first embodiment is described, the constitution of a light-emitting device produced by the method for producing a light-emitting device according to the first embodiment will be described with reference to FIGS. 1 and 2.

FIG. 1 is a sectional view of a light-emitting device. FIG. 2 is a plan view of the light-emitting device shown in FIG. 1. As shown in FIGS. 1 and 2, a light-emitting device 1 according to an embodiment is generally classified into a “surface mounting type”. The light-emitting device 1 includes a substrate 10, a blue LED 30 bonded to the surface of the substrate 10 as a light-emitting element, a reflector 20 provided on the surface of the substrate 10 so as to surround the blue LED 30, and a transparent sealing resin 40 with which the reflector 20 is filled and which seals the blue LED 30. In FIG. 2, the transparent sealing resin 40 is not shown.

In the substrate 10, a copper plating plate 14 is wired on the surface of an insulating base 12, and a silver plating layer 16 is formed on the surface of the copper plating plate 14. The silver plating layer 16 is disposed on the surface of the substrate 10, and serves as an electrode electrically connected to the blue LED 30. As long as the silver plating layer 16 is a plating layer containing silver, the silver plating layer 16 may have any of compositions. The silver plating layer 16 may be formed by plating only silver, for example, and the silver plating layer 16 may be formed by plating nickel and silver in this order. The copper plating plate 14 and the silver plating layer 16 are insulated on an anode side and a cathode side. The copper plating plate 14 and the silver plating layer 16 on the anode side, and the copper plating plate 14 and the silver plating layer 16 on the cathode side can be insulated by separating the copper plating plate 14 and the silver plating layer 16 on the anode side from the copper plating plate 14 and the silver plating layer 16 on the cathode side, and appropriately inserting an insulating layer made of a resin and ceramic or the like therebetween, for example.

The blue LED 30 is die-bonded to the silver plating layer 16 on any one of the anode side and the cathode side, and is electrically connected to the silver plating layer 16 via a die bonding material 32. The blue LED 30 is wire-bonded to the silver plating layer 16 on the other of the anode side and the cathode side, and is electrically connected to the silver plating layer 16 via a bonding wire 34.

The reflector 20 is filled with the transparent sealing resin 40 for sealing the blue LED 30, and reflects a light emitted from blue LED 30 to the surface side of the light-emitting device 1. The reflector 20 stands on the surface of the substrate 10 so as to surround the blue LED 30. That is, the reflector 20 includes an inner circumferential surface 20a which forms an inner space 22 uprising from a surface 10a of the substrate 10 so as to surround the blue LED 30 and accommodating the blue LED 30 on the inner side and is circularly formed in plan view (see FIG. 2), a top surface 20b which is located outside the inner space 22 so as to be adjacent to the inner circumferential surface 20a, and spreads towards a side opposite to the inner space 22 from a front side edge of the inner circumferential surface 20a, and an outer circumferential surface 20c falling to the surface 10a of the substrate 10 from an outer side edge of the top surface 20b and formed in a rectangle in plan view (see FIG. 2). Although the shapes of the inner circumferential surface 20a and the outer circumferential surface 20c are not particularly limited, from the viewpoint of an improvement in the illuminance of the light-emitting device 1, it is preferable to form the inner circumferential surface 20a in a truncated cone shape (funnel shape) of which the diameter increases as it aparts from the substrate 10, and from the viewpoint of an improvement in the integration degree of the light-emitting device 1, it is preferable to form the outer circumferential surface 20c in a square shape perpendicular to the substrate 10. In the drawings, as a formation example of the inner circumferential surface 20a, a lower portion located on the substrate 10 side is perpendicular to the substrate 10, and an upper portion located on a side opposite to the substrate 10 has a diameter increased as it is separated from the substrate 10.

The reflector 20 is made of a cured product of a thermosetting resin composition containing a white pigment. From the viewpoint of the formation easiness of the reflector 20, the thermosetting resin composition can be preferably pressure molded at room temperature (25° C.) before thermal curing.

Various thermosetting resins such as an epoxy resin, a silicone resin, an urethane resin, and a cyanate resin can be used as a thermosetting resin contained in the thermosetting resin composition. Since the adhesion properties of the epoxy resin to various materials are excellent, the epoxy resin is particularly preferable.

Alumina, magnesium oxide, antimony oxide, titanium oxide, or zirconium oxide can be used as the white pigment. Among them, in point of light reflectivity, titanium oxide is preferable. An inorganic hollow particle may be used as the white pigment. Specific examples of the inorganic hollow particle include sodium silicate glass, aluminosilicate glass, sodium borosodium silicate glass, and shirasu.

The inner space 22 formed by the inner circumferential surface 20a of the reflector 20 is filled with the transparent sealing resin 40 to seal the blue LED 30. The transparent sealing resin 40 is made of a transparent sealing resin having a translucency. The transparent sealing resin contains also a translucent resin besides a completely transparent resin. The transparent sealing resin preferably has an elastic modulus of 1 MPa or less at room temperature (25° C.). In particular, in point of a transparency, it is preferable to employ a silicone resin or an acrylic resin. The transparent sealing resin may further contain an inorganic filler diffusing a light, or a fluorescent material 42 producing a white light using a blue light emitted from the blue LED 30 as an excitation source.

In the light-emitting device 1 according to the present embodiment, the silver plating layer 16 is covered with a silver-sulfidation-preventing film 50, and the transparent sealing resin 40 and the reflector 20 are joined to each other.

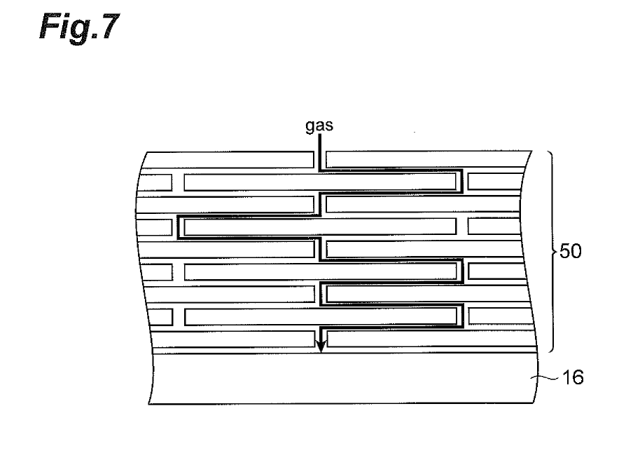

The sulfidation of the silver plating layer 16 is suppressed by covering the silver plating layer 16 with the silver-sulfidation-preventing film 50, and the silver-sulfidation-preventing film 50 is formed of the above-mentioned silver-sulfidation-preventing material of the present embodiment. When the silver-sulfidation-preventing material contains montmorillonite as the clay and a binder having a polar group, a film having a long gas path route and excellent gas barrier properties is formed as shown in FIG. 7, and furthermore, a hydroxyl group (—OH) on the surface of the clay is hydrogen-bonded to the polar group of the binder to make the film firmer. Thereby, an effect of filling a gap between the clays, and an effect of improving resistance characteristics against cracks caused by heat expansion are obtained, and a silver-sulfidation-preventing film having more excellent gas barrier properties is obtained.

The film thickness of the silver-sulfidation-preventing film 50 is preferably 0.01 μm or more and 1000 μm or less, more preferably 0.05 μm or more and 100 μm or less, and further preferably 0.05 μm or more and 10 μm or less. The film thickness of the silver-sulfidation-preventing film 50 is set to 0.01 μm or more and 1000 μm or less, and thereby both the gas barrier properties to the silver plating layer 16 and the transparency of the silver-sulfidation-preventing film 50 can be achieved. The film thickness of the silver-sulfidation-preventing film 50 is set to 0.03 μm or more and 500 μm or less, 0.05 μm or more and 100 μm or less, 0.05 μm or more and 10 μm or less, and 0.05 μm or more and 1 μm or less, and thereby the effect can be further improved.

The silver-sulfidation-preventing film 50 is formed of the silver-sulfidation-preventing material of the present embodiment, and thereby the cracks are less likely to be generated even in the film thickness.

The film thickness can be adjusted by, for example, changing the content of the solvent in the silver-sulfidation-preventing material to appropriately adjust the concentrations of the clay and the binder. The film thickness can be adjusted also by the dripping amount and the dripping frequency of the silver-sulfidation-preventing material.

Next, a method for producing a light-emitting device 1 according to a first embodiment will be described.

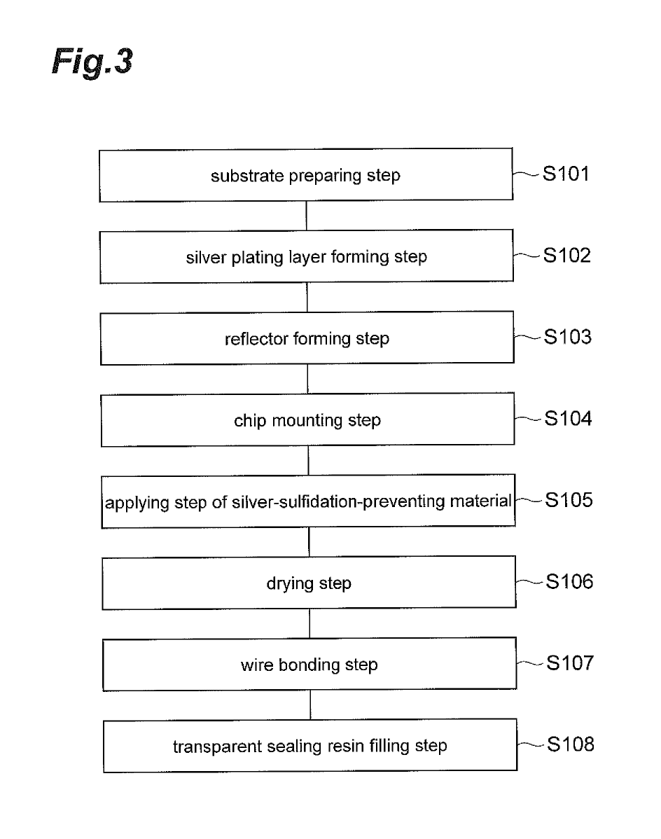

FIG. 3 is a flow chart showing a method for producing a light-emitting device according to the first embodiment. As shown in FIG. 3, in the method for producing the light-emitting device, first, an insulating base 12 in which a copper plating plate 14 is wired on a surface is prepared as a substrate preparing step (step S101), and a silver plating layer 16 is formed on the surface of the copper plating plate 14 as a silver plating layer forming step (step S102).

Next, a reflector 20 is formed on the surface of the substrate 10 as a reflector forming step (step S103), and a blue LED 30 is mounted on the substrate 10 as a chip mounting step (step S104). The blue LED 30 is mounted on the substrate 10 by die-bonding the blue LED 30 to the silver plating layer 16 on any one of an anode side and a cathode side in an inner space 22 surrounded with the reflector 20. Thereby, the blue LED 30 is electrically connected to the silver plating layer 16 on any one of the anode side and the cathode side via a die bonding material 32, and the blue LED 30 is accommodated in the inner space 22 in a state where the blue LED 30 is surrounded with the reflector 20.

Next, as a step of applying a silver-sulfidation-preventing material (step S105), the silver-sulfidation-preventing material of the present embodiment is applied to the silver plating layer 16 to cover the silver plating layer 16 with the silver-sulfidation-preventing material.

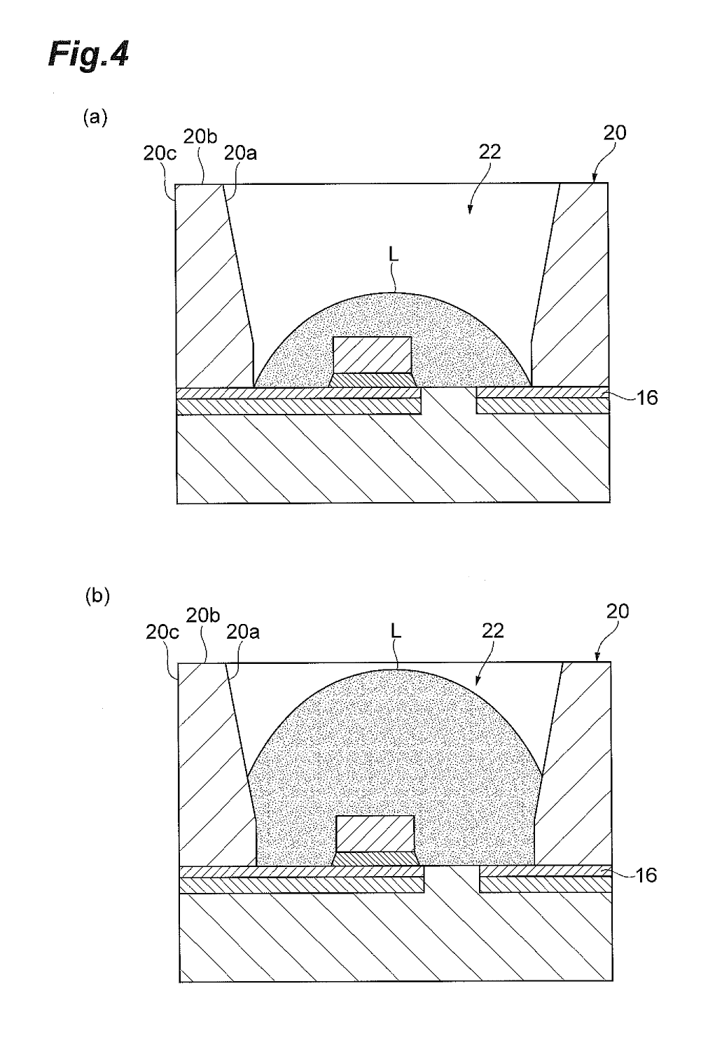

The silver-sulfidation-preventing material is applied by dripping or sparging the silver-sulfidation-preventing material into the inner space 22 from the surface side of the substrate 10, for example, in an applying step of the silver-sulfidation-preventing material (step S105). At this time, the dripping amount or the sparging amount of the silver-sulfidation-preventing material is regulated so that at least the silver plating layer 16 is wholly covered with a silver-sulfidation-preventing material L. In this case, for example, as shown in FIG. 4(a), the silver-sulfidation-preventing material L may be dripped or sparged into the inner space 22 so that the silver plating layer 16 and the blue LED 30 are wholly covered with the silver-sulfidation-preventing material L, and as shown in FIG. 4(b), the silver-sulfidation-preventing material L may be dripped or sparged into the inner space 22 so that the silver plating layer 16 and the blue LED 30 are wholly covered with the silver-sulfidation-preventing material L and an inner circumferential surface 20a of the reflector 20 is partially covered with the silver-sulfidation-preventing material L.

Next, a coated film made of the silver-sulfidation-preventing material applied to the silver plating layer 16 is dried as a drying step (step S106) to form a silver-sulfidation-preventing film 50.

The drying step can be performed at a temperature at which a solvent is volatilized, and for example, it is preferable to set the temperature range to 30° C. or more and 80° C. or less, more preferable to set the temperature range to 30° C. or more and 70° C. or less, and further preferable to set the temperature range to 30° C. or more and 60° C. or less when water is used as a solvent. A time for maintaining the temperature region can be set to 1 minute or more, for example; from the viewpoint of obtaining excellent film formability, it is preferable to set the time to 5 minutes or more and 1 day or less; and from the viewpoint of shortening a step time, it is more preferable to set the time to 5 minutes or more and 30 minutes or less.

In the drying step when the solvent contains water and alcohol, for example, it is preferable to set the temperature range to 30° C. or more and 80° C. or less, more preferable to set the temperature range to 35° C. or more and 80° C. or less, and further preferable to set the temperature range to 40° C. or more and 80° C. or less. A time for maintaining the temperature region can be set to 1 minute or more, for example; from the viewpoint of obtaining excellent film formability, it is preferable to set the time to 5 minutes or more and 30 minutes or less; and from the viewpoint of shortening a step time, it is more preferable to set the time to 5 minutes or more and 15 minutes or less.

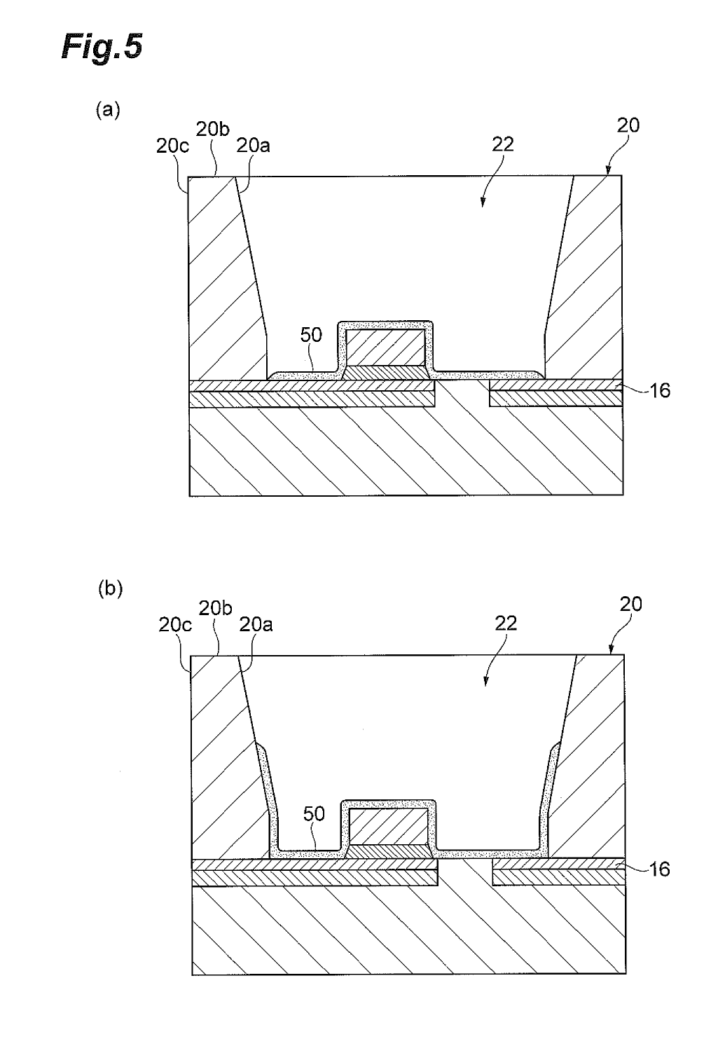

Thus, by performing the drying step, a clay diluted solution L shown in FIG. 4(a) turns into the silver-sulfidation-preventing film 50 wholly covering the silver plating layer 16 and the blue LED 30, as shown in FIG. 5(a), and the clay diluted solution L shown in FIG. 4(b) turns into the silver-sulfidation-preventing film 50 wholly covering the silver plating layer 16 and the blue LED 30, and partially covering the inner circumferential surface 20a of the reflector 20, as shown in FIG. 5(b).

In the present embodiment, it is preferable to sufficiently dry the silver-sulfidation-preventing film 50 under conditions of 150° C. and 30 minutes after the drying step. Thereby, an effect of further improving silver-sulfidation-preventing property by decreasing a distance between layers of the clay can be obtained.

As shown in FIG. 3, after the drying step (step S106) is completed, next, the blue LED 30 and the silver plating layer 16 on the other of the anode side and the cathode side are wire-bonded to each other as a wire bonding step (step S107). At this time, the blue LED 30 and the silver plating layer 16 are electrically connected to each other by bonding both the ends of the wire to the blue LED 30 and the silver plating layer 16 so as to break through the blue LED 30 and the silver-sulfidation-preventing film 50 with which the silver plating layer 16 is covered. The silver-sulfidation-preventing film 50 can be broken through by regulating the layer thickness of the silver-sulfidation-preventing film 50, regulating a load of a bonding head for performing wire bonding, or by vibrating the bonding head, for example.

Next, as a transparent sealing resin filling step (step S108), the inner space 22 formed by the inner circumferential surface 20a of the reflector 20 is filled with the transparent sealing resin 40 containing the fluorescent material 42. Thereby, the blue LED 30 and the silver plating layer 16 are sealed by the transparent sealing resin 40 (transparent sealing portion).

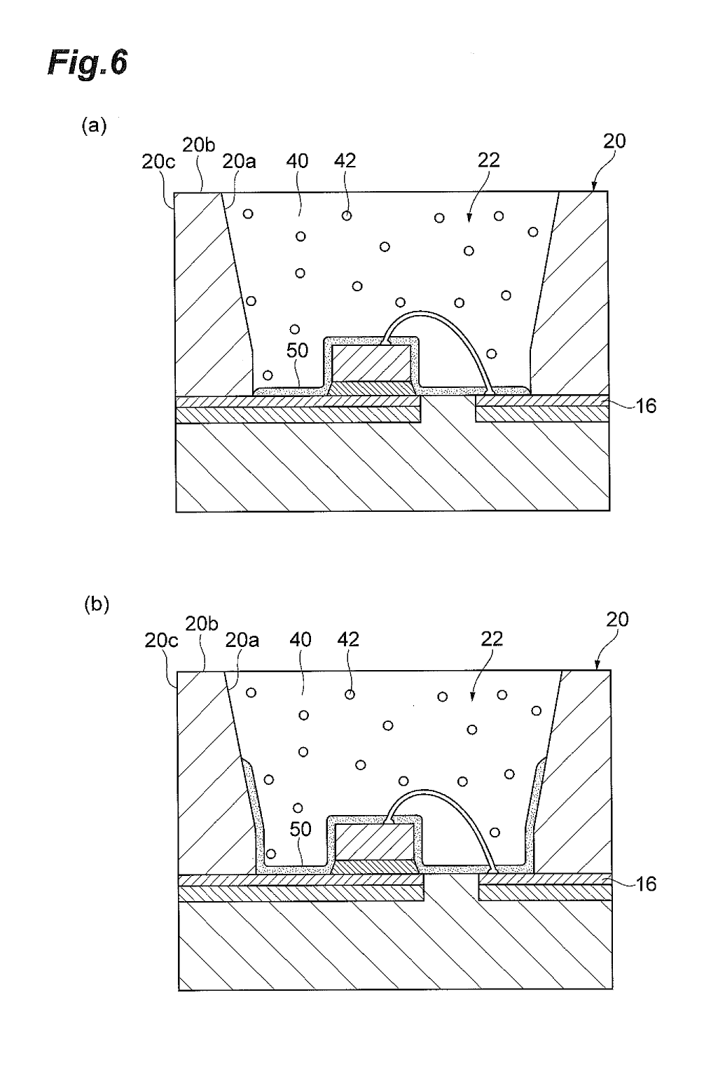

Thus, by performing the transparent sealing resin filling step, the light-emitting device 1 shown in FIG. 5(a) serves as the light-emitting device 1 in which the silver plating layer 16 and the blue LED 30 are sealed by the transparent sealing resin 40 in a state where the silver plating layer 16 and the blue LED 30 are wholly covered with the silver-sulfidation-preventing film 50 as shown in FIG. 6(a). As shown in FIG. 6(b), the light-emitting device 1 shown in FIG. 5(b) serves as the light-emitting device 1 in which the silver plating layer 16 and the blue LED 30 are sealed by the transparent sealing resin 40 in a state where the silver plating layer 16 and the blue LED 30 are wholly covered with the silver-sulfidation-preventing film 50 and the inner circumferential surface 20a of the reflector 20 is partially covered with the silver-sulfidation-preventing film 50.

Thus, according to the method for producing the light-emitting device 1 according to the first embodiment, the silver-sulfidation-preventing film 50 in which the clay contained in the silver-sulfidation-preventing material is laminated is formed by covering the silver plating layer 16 with the silver-sulfidation-preventing material of the present embodiment, and then drying the coated film made of the silver-sulfidation-preventing material, and the silver plating layer 16 is covered with the silver-sulfidation-preventing film 50. Thereby, the silver-sulfidation-preventing film 50 capable of suitably covering the silver plating layer 16 can be formed.

The silver-sulfidation-preventing film covering the silver plating layer can be easily formed by dripping or sparging the silver-sulfidation-preventing material of the present embodiment into the inner space 22 of the reflector 20 provided in the light-emitting device 1.

### Second Embodiment

Next, the second embodiment will be described. Although a method for producing a light-emitting device according to the second embodiment is fundamentally the same as the method for producing a light-emitting device according to the first embodiment, only the order of the step of the second embodiment is different from that of the method for producing a light-emitting device according to the first embodiment. For this reason, in the following description, only portions different from the method for producing a light-emitting device according to the first embodiment will be described, and the description of the same portions as those of the method for producing a light-emitting device according to the first embodiment will be omitted.

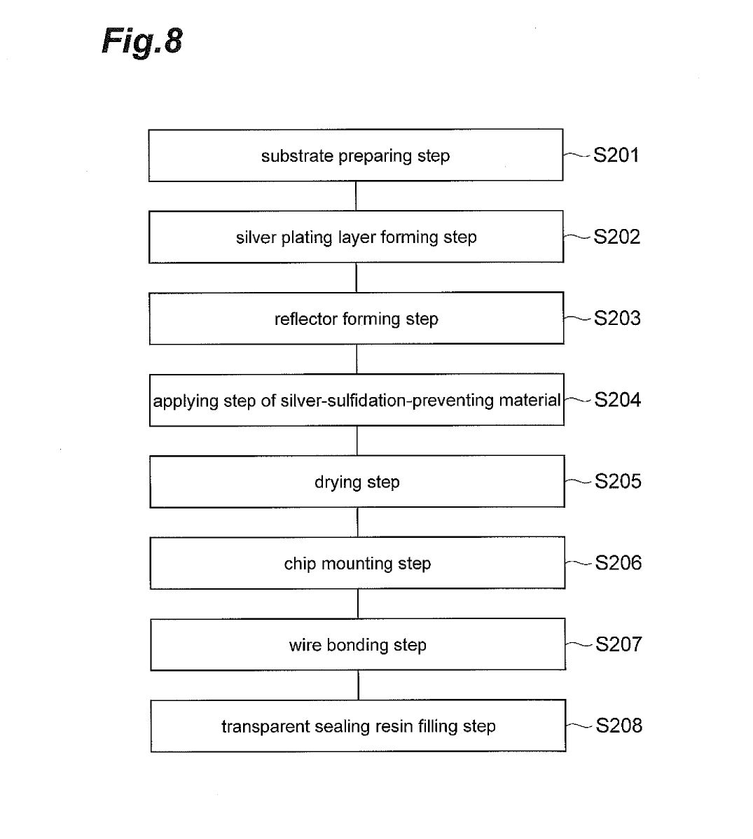

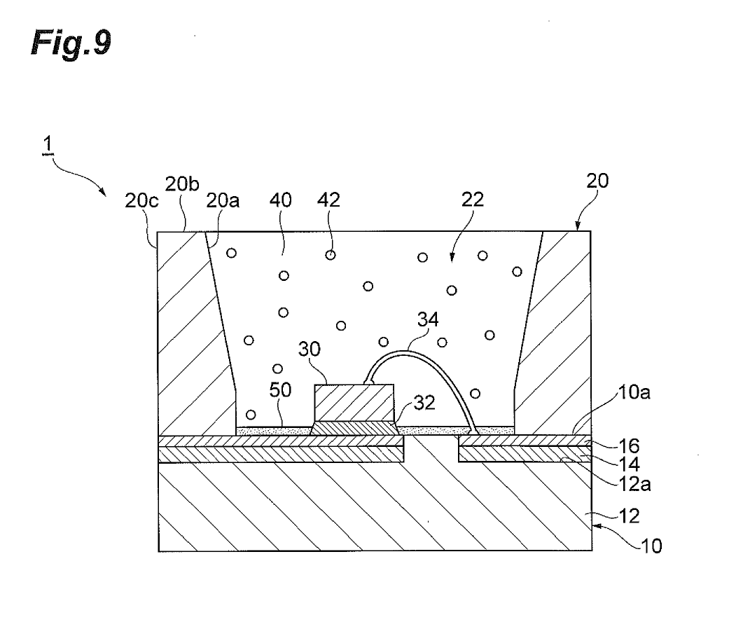

FIG. 8 is a flow chart showing a method for producing a light-emitting device according to the second embodiment. FIG. 9 is a sectional view of the light-emitting device produced by the producing method of FIG. 8.

As shown in FIG. 8, a method for producing a light-emitting device 1 according to the second embodiment first performs a substrate preparing step (step S201), a silver plating layer forming step (step S202), and a reflector forming step (step S203) in this order as in the first embodiment. The substrate preparing step (step S201), the silver plating layer forming step (step S202), and the reflector forming step (step S203) are the same as the substrate preparing step (step S101), the silver plating layer forming step (step S102), and the reflector forming step (step S103) of the first embodiment.

Next, as an applying step (step S204) of a silver-sulfidation-preventing material, the silver-sulfidation-preventing material of the present embodiment is applied to a silver plating layer 16 to cover the silver plating layer 16 with the silver-sulfidation-preventing material.

Next, a coated film made of the silver-sulfidation-preventing material applied to the silver plating layer 16 is dried as a drying step (step S205) to form a silver-sulfidation-preventing film 50. The drying step (step S205) can be performed as in the drying step (step S106) of the first embodiment.

Next, a blue LED 30 is die-bonded to the silver plating layer 16 on any one of an anode side and a cathode side as a chip mounting step (step S206). At this time, the blue LED 30 and the silver plating layer 16 are electrically connected to each other by bonding the blue LED 30 to the silver plating layer 16 so as to break through the silver-sulfidation-preventing film 50 with which the silver plating layer 16 is covered as in the wire bonding step (step S107) of the first embodiment.

Next, the blue LED 30 and the silver plating layer 16 on the other of the anode side and the cathode side are wire-bonded to each other as a wire bonding step (step S207). Since the silver plating layer 16 is covered with the silver-sulfidation-preventing film 50 at this time, one end of the wire is bonded to the silver plating layer 16 so as to break through the silver-sulfidation-preventing film 50 with which the silver plating layer 16 is covered as in the wire bonding step (step S107) of the first embodiment. On the other hand, since the blue LED 30 is not covered with the silver-sulfidation-preventing film 50, the other end of a bonding wire 34 can be bonded to the blue LED 30 as usual. Thereby, the blue LED 30 and the silver plating layer 16 are electrically connected to each other.

Next, a transparent sealing resin filling step is performed as step S208.

Thus, according to the method for producing a light-emitting device according to the second embodiment, as shown in FIG. 9, the light-emitting device 1 in which the blue LED 30 is not covered with the silver-sulfidation-preventing film 50 can be produced by performing the chip mounting step after the applying step and the drying step of the silver-sulfidation-preventing material. Thereby, in the wire bonding step, it is unnecessary to break through the silver-sulfidation-preventing film 50 as in the method for producing a light-emitting device according to the first embodiment when one end of the bonding wire 34 is bonded to the blue LED 30.

### Third Embodiment

Next, the third embodiment will be described. Although a method for producing a light-emitting device according to the third embodiment is fundamentally the same as the method for producing a light-emitting device according to the first embodiment, only the order of the steps of the third embodiment is different from that of the method for producing a light-emitting device according to the first embodiment. For this reason, in the following description, only portions different from the method for producing a light-emitting device according to the first embodiment will be described, and the description of the same portions as those of the method for producing a light-emitting device according to the first embodiment will be omitted.

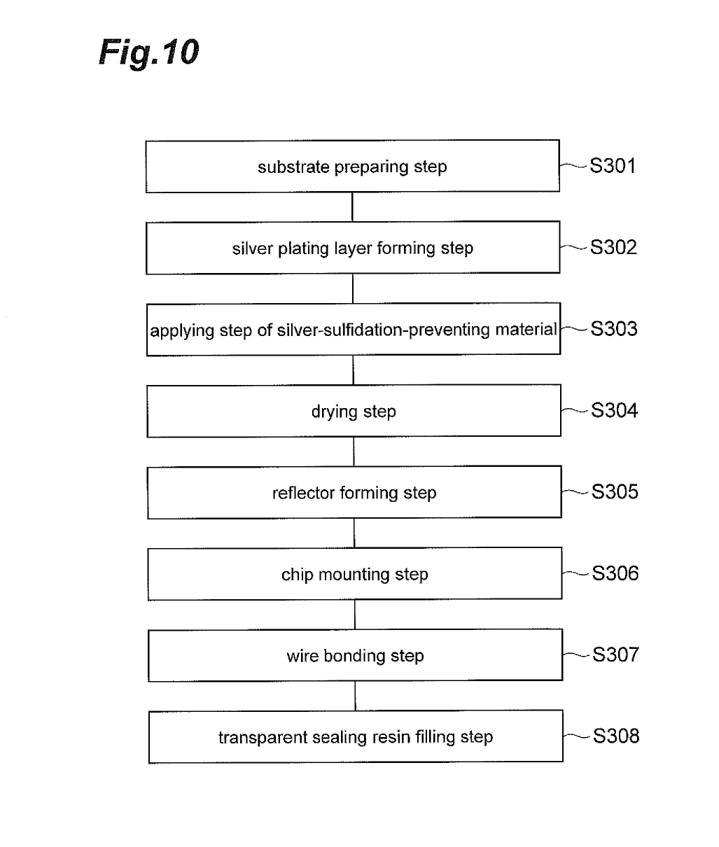

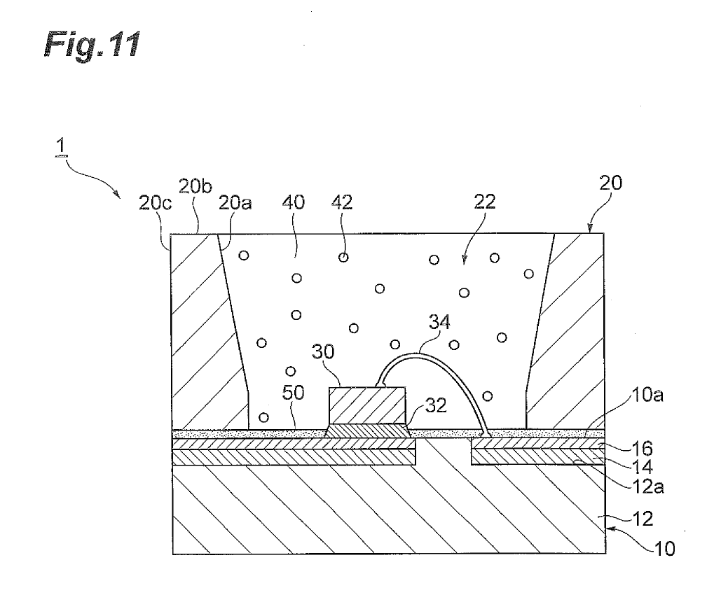

FIG. 10 is a flow chart showing a method for producing a light-emitting device according to the third embodiment. FIG. 11 is a sectional view of the light-emitting device produced by the producing method of FIG. 10.

As shown in FIG. 10, a method for producing a light-emitting device 1 according to the third embodiment first performs a substrate preparing step (step S301) and a silver plating layer forming step (step S302) in this order as in the first embodiment. The substrate preparing step (step S301) and the silver plating layer forming step (step S302) are the same as the substrate preparing step (step S101) and the silver plating layer forming step (step S102) of the first embodiment.

Next, as an applying step (step S303) of a silver-sulfidation-preventing material, the silver-sulfidation-preventing material of the present embodiment is applied to a silver plating layer 16 to cover the silver plating layer 16 with the silver-sulfidation-preventing material. Although it is preferable to apply the silver-sulfidation-preventing material to the whole surface of a substrate 10 on which the silver plating layer 16 is formed from the viewpoint of workability at this time, the silver-sulfidation-preventing material may be applied so as to cover only the silver plating layer 16.

Next, a coated film made of the silver-sulfidation-preventing material applied to the silver plating layer 16 is dried as a drying step (step S304), to form a silver-sulfidation-preventing film 50. The drying step (step S304) can be performed as in the drying step (step S106) of the first embodiment.

Next, a reflector 20 is formed on the surface of the substrate 10 as a reflector forming step (step S305). When the silver-sulfidation-preventing material is applied to the whole surface of the substrate 10 in the applying step (step S303) of the silver-sulfidation-preventing material at this time, the reflector 20 is formed on the surface of the silver-sulfidation-preventing film 50 covering the surface of the substrate 10.

Next, a blue LED 30 is die-bonded to the silver plating layer 16 on any one of an anode side and a cathode side as a chip mounting step (step S306). At this time, the blue LED 30 and the silver plating layer 16 are electrically connected to each other by bonding the blue LED 30 to the silver plating layer 16 so as to break through the silver-sulfidation-preventing film 50 with which the silver plating layer 16 is covered as in the wire bonding step (step S107) of the first embodiment.

Next, the blue LED 30 and the silver plating layer 16 on the other of the anode side and the cathode side are wire-bonded to each other as a wire bonding step (step S207). Since the silver plating layer 16 is covered with the silver-sulfidation-preventing film 50 at this time, one end of the wire is bonded to the silver plating layer 16 so as to break through the silver-sulfidation-preventing film 50 with which the silver plating layer 16 is covered as in the wire bonding step (step S107) of the first embodiment. On the other hand, since the blue LED 30 is not covered with the silver-sulfidation-preventing film 50, the other end of a bonding wire 34 can be bonded to the blue LED 30 as usual. Thereby, the blue LED 30 and the silver plating layer 16 are electrically connected to each other.

Next, a transparent sealing resin filling step is performed as step S308.

Thus, according to the method for producing a light-emitting device according to the third embodiment, as shown in FIG. 11, the light-emitting device 1 in which the blue LED 30 is not covered with the silver-sulfidation-preventing film 50 can be produced by performing the reflector forming step and the chip mounting step after the applying step and the drying step of the silver-sulfidation-preventing material. Thereby, in the wire bonding step, it is unnecessary to break through the silver-sulfidation-preventing film 50 as in the method for producing a light-emitting device according to the first embodiment when one end of the bonding wire 34 is bonded to the blue LED 30.

As described above, although the preferred embodiments of the present invention have been described, the present invention is not limited to the embodiments.

For example, although the wire bonding is performed after the silver-sulfidation-preventing film is formed in the embodiments, the silver-sulfidation-preventing film can be formed on the silver plating layer by applying and drying the silver-sulfidation-preventing material of the present embodiment after the wire bonding. The silver-sulfidation-preventing material of the present embodiment can sufficiently prevent the coated film made of the silver-sulfidation-preventing material from adhering to the wire for the wire bonding in a curtain shape and remaining on the wire. In this case, it is preferable to set the drying temperature to 40° C. or less, and more preferable to set the drying temperature to 25° C. or less.

Although the embodiments employing the blue LED 30 generating a blue light as the light emitting diode bonded to the light-emitting device 1 have been described, a light emitting diode generating a light other than the blue light may be employed.

Although the light-emitting devices 1 of the embodiments including the reflector 20 surrounding the blue LED 30 have been described, the light-emitting devices 1 may not include such a reflector 20.

Since the silver-sulfidation-preventing material of the present embodiment can form the silver-sulfidation-preventing film having excellent silver-sulfidation-preventing property, sufficient silver-sulfidation-preventing property can be obtained even in a light-emitting device in which Y₂O₂S:Eu (red), ZnS:Cu (green), and ZnS:Ag (blue) conventionally used as the fluorescent material, and a sulfur-containing compound such as a compound shown in Japanese Patent Application Laid-Open No. 8-085787 are used.

The silver-sulfidation-preventing material of the present embodiment can also be applied to a plasma display and a liquid crystal display or the like on which the LED including the lead frame containing silver is mounted, for example, in addition to the above-mentioned light-emitting device.

### EXAMPLES

The present invention will now be specifically described by Examples and Comparative Examples, with the understanding that the present invention is not limited thereby.

### Preparation of Silver-Sulfidation-Preventing Material

### Preparation Example 1

55.1 g of ultrapure water and 0.16 g of a powder of Kunipia F (trade name, manufactured by Kunimine Industries Co., Ltd.) were charged into a container, and the container was shaken and stirred by hands. After 36.74 g of isopropanol was further added into the container, the contents were mixed at 2000 rpm for 20 minutes by using a rotation/revolution mixer (ARE-310 manufactured by Thinly), and then defoamed at 2200 rpm for 10 minutes. Then, 8 g of S LEC KX-1 (trade name, manufactured by Sekisui Chemical Co., Ltd., a water/alcohol mixed solution of a butyral resin of which a degree of acetalization was about 8 mol %, solid content: 8% by mass) as a binder was charged; and the contents were mixed at 2000 rpm for 20 minutes by using the rotation/revolution mixer (ARE-310 manufactured by Thinly) again, and then defoamed at 2200 rpm for 10 minutes to obtain a mixed solution of clay and a binder as a silver-sulfidation-preventing material.

### Preparation Example 2

58.7 g of ultrapure water and 0.16 g of a powder of Kunipia F (trade name, manufactured by Kunimine Industries Co., Ltd.) were charged into a container, and the container was shaken and stirred by hands. After 39.14 g of isopropanol was further added into the container, the contents were mixed at 2000 rpm for 20 minutes by using a rotation/revolution mixer, and then defoamed at 2200 rpm for 10 minutes. Then, 2 g of S LEC KX-1 as a binder was charged; and the contents were mixed at 2000 rpm for 20 minutes by using the rotation/revolution mixer again, and then defoamed at 2200 rpm for 10 minutes to obtain a mixed solution of clay and a binder as a silver-sulfidation-preventing material.

### Preparation Example 3

58.81 g of ultrapure water and 0.16 g of a powder of Kunipia F (trade name, manufactured by Kunimine Industries Co., Ltd.) were charged into a container, and the container was shaken and stirred by hands. After 39.2 g of isopropanol was further added into the container, the contents were mixed at 2000 rpm for 20 minutes by using a rotation/revolution mixer, and then defoamed at 2200 rpm for 10 minutes. Then, 1.83 g of SUPERFLEX 130 (trade name, manufactured by Dai-ichi Kogyo Seiyaku Co., Ltd., a self-emulsifying water dispersion polyether-based polyurethane emulsion, solid content: 35% by mass) as a binder was charged; and the contents were mixed at 2000 rpm for 20 minutes by using the rotation/revolution mixer again, and then defoamed at 2200 rpm for 10 minutes to obtain a mixed solution of clay and a binder as a silver-sulfidation-preventing material.

### Comparative Preparation Example 1

99 g of ultrapure water and 1 g of Carboxymethyl Cellulose (trade name, manufactured by Wako Pure Chemical Industries, Ltd.) as a binder were charged into a separable flask; a stirring propeller was set; the separable flask was charged into a waterbath set to 70° C.; and the contents were heated and mixed for 30 minutes while being stirring at a stirring speed of 200 rpm to obtain a binder aqueous solution.

<Evaluation of Crack Resistance, Silver-Sulfidation-Preventing Property, and Yellowing Resistance>

The crack resistance, the silver-sulfidation-preventing property, and the yellowing resistance of the silver-sulfidation-preventing material produced above were evaluated in accordance with the following methods.

[Evaluation of Crack Resistance]

3 μL of a silver-sulfidation-preventing material was dripped into “TOP LED OP4” (manufactured by Enomoto Co., Ltd.) serving as an LED lead frame in which a silver plating layer was provided on a copper plate by a micropipetter. The lead frame into which the silver-sulfidation-preventing material was dripped was charged into a constant-temperature bath, and dried at 50° C. for 10 minutes. After drying, the temperature of the constant-temperature bath was increased to 150° C., and the lead frame was heated for 30 minutes, to obtain test samples. The film thicknesses after drying are shown in Table 1.

The test samples were observed by an electron microscope, and the presence or absence of cracks on a film was evaluated. A case where the cracks were present was defined as “◯” and a case where the cracks were absent was defined as “x”.

[Evaluation of Yellowing Resistance]

Test samples were obtained as in the evaluation of the crack resistance.

The test samples were observed with a magnifying lens; a case where the yellowing was present was defined as “◯”; and a case where the yellowing was absent was defined as “x”.

[Evaluation of Silver-Sulfidation-Preventing Property]

Test samples were obtained as in the evaluation of the crack resistance.

An aluminum cup into which a sulfur powder (0.5 g) was charged was placed into a sealable glass bottle, and a metal mesh made of stainless steel was put on the cup. Next, the test samples were placed so that the samples did not overlap each other with the side of the metal mesh onto which the silver-sulfidation-preventing material was dripped up. The glass bottle was sealed, and then stored at 100° C. for 2 hours. The test samples were taken out from the glass bottle; the sulfidation-preventing properties were observed with an optical microscope; a case where a silver plating surface was not discolored at all after and before the test was defined as “◯”; a case where the silver plating surface was partially discolored by sulfidation was defined as “Δ”; and a case where the silver plating surface was wholly discolored was defined as “x”.

TABLE 1

| silver- | | | | | Silver- | |
|---|---|---|---|---|---|---|
| sulfidation- | concentration | concentration | film thickness | | sulfidation- | |
| preventing | of clay | of binder | after drying | crack | preventing | yellowing |
| material | (% by mass) | (% by mass) | (nm) | resistance | property | resistance |
| Preparation | 0.16 | 0.64 | 600 | ◯ | ◯ | ◯ |
| Example 1 | | | | | | |
| Preparation | 0.16 | 0.16 | 300 | ◯ | ◯ | ◯ |
| Example 2 | | | | | | |
| Preparation | 0.16 | 0.64 | 600 | ◯ | ◯ | ◯ |
| Example 3 | | | | | | |
| Comparative | 0 | 1.0 | 800 | X | Δ | X |
| Preparation | | | | | | |
| Example 1 | | | | | | |

As shown in Table 1, it was confirmed that the silver-sulfidation-preventing materials of Preparation Examples 1 to 3 containing the clay and the binder could form the film achieving both sufficient crack resistance and yellowing resistance and excellent silver-sulfidation-preventing property.

### SEQUENCE LISTING

1 . . . light-emitting device, 10 . . . substrate, 10a . . . surface of substrate, 12 . . . base, 14 . . . copper plating plate, 16 . . . silver plating layer, 20 . . . reflector (light reflecting part), 20a . . . inner circumferential surface, 20b . . . top surface, 20c . . . outer circumferential surface, 22 . . . inner space, 30 . . . blue LED (blue light emitting diode), 32 . . . die bonding material, 34 . . . bonding wire, 40 . . . transparent sealing resin (transparent sealing part), 42 . . . fluorescent material, 50 . . . silver-sulfidation-preventing film, L . . . silver-sulfidation-preventing material

1. A silver-sulfidation-preventing material comprising:
clay; and
a binder.

2. The silver-sulfidation-preventing material according to claim 1, wherein a mass ratio of the clay to the binder is 75/25 to 5/95.

3. The silver-sulfidation-preventing material according to claim 1, wherein the silver-sulfidation-preventing material comprises an aqueous binder as the binder.

4. The silver-sulfidation-preventing material according to claim 1, wherein a total content of the clay and the binder is 80% by mass or more based on a total amount of a solid content of the silver-sulfidation-preventing material.

5. A method for forming a silver-sulfidation-preventing film,
the method comprising:
an applying step of applying the silver-sulfidation-preventing material according to claim 1 onto a surface of a metal layer comprising silver to form a coated film made of the silver-sulfidation-preventing material; and
a drying step of drying the coated film.

6. The method for forming a silver-sulfidation-preventing film according to claim 5, wherein the metal layer is a silver plating layer.

7. A method for producing a light-emitting device,
the light-emitting device comprising a substrate having a silver plating layer, and a light-emitting element mounted on the substrate,
the method comprising:
an applying step of applying the silver-sulfidation-preventing material according to claim 1 onto a surface of the silver plating layer to form a coated film made of the silver-sulfidation-preventing material; and
a drying step of drying the coated film.

8. A light-emitting device comprising:
a substrate having a silver plating layer;
a light-emitting element mounted on the substrate; and
a silver-sulfidation-preventing film provided on a surface of the silver plating layer,
wherein the silver-sulfidation-preventing film comprises clay and a binder.

9. The light-emitting device according to claim 8, wherein a mass ratio of the clay and the binder in the silver-sulfidation-preventing film is 75/25 to 5/95.

10. The light-emitting device according to claim 8, wherein the silver-sulfidation-preventing film comprises an aqueous binder as the binder.

11. The light-emitting device according to claim 8, wherein a total concentration of the clay and the binder in the silver-sulfidation-preventing film is 80% by mass or more.
